(19) United States
(12) Patent Application Publication
(10) Pub. No.: US 2026/0190267 A1
(43) Pub. Date: Jul. 2, 2026

(54) SPLICING DISPLAY MODULE AND DISPLAY DEVICE

(71) Applicant: TCL CHINA STAR OPTOELECTRONICS TECHNOLOGY CO., LTD., Shenzhen (CN)

(72) Inventors: Pengfei WEI, Shenzhen (CN); Hongyuan XU, Shenzhen (CN); Fengchao XU, Shenzhen (CN)

(73) Assignee: TCL CHINA STAR OPTOELECTRONICS TECHNOLOGY CO., LTD., Shenzhen (CN)

(21) Appl. No.: 19/232,828

(22) Filed: Jun. 9, 2025

(30) Foreign Application Priority Data
Dec. 30, 2024 (CN) 202411984967.8

(51) Int. Cl. H05K 5/30

(52) U.S. Cl. CPC H05K 5/30

(57) ABSTRACT

The present application provides a splicing display module and display device, the splicing display module comprises a first display module and a second display module spliced to each other, the first display module comprises a first substrate and a second substrate disposed opposite to each other, the main body of the first substrate and the second substrate are disposed opposite to each other, the extension portion of the first substrate is disposed to extend beyond the edge of the second substrate, the second display module is at least disposed on the extension portion and is in electrical driving connection with the driving trace.

This application claims the benefit of Chinese Patent Application No. 202411984967.8 filed on Dec. 30, 2024 and entitled “SPLICING DISPLAY MODULE AND DISPLAY DEVICE”, the disclosures of which are incorporated by reference herein in their entirety.

### TECHNICAL FIELD

The application relates to the technical field of display, and in particular, relates to a splicing display module and a display device.

### BACKGROUND

With the rapid development of the display technology, the demand of the people for the display device is continuously increasing. To achieve a larger display area, the application of splicing a plurality of display panels together is becoming more widespread.

Due to each display panel configured as splicing unit has a certain width of border, the splicing display module formed by splicing has a seam that causes a serious sense of segmentation to the overall picture, severely affecting the overall effect of the splicing display image.

Therefore, it is necessary to provide a splicing display module and a display device to improve this deficiency.

### SUMMARY

According to the first aspect of the present application, a splicing display module is provided, which comprises a first display module and a second display module spliced to each other, wherein the first display module comprises a first substrate and a second substrate disposed opposite to each other, the first substrate comprises a main body and an extension portion, the main body and the second substrate are disposed opposite to each other, the extension portion is disposed to extend beyond the edge of the second substrate, a driving trace is disposed on the extension portion; the second display module is at least disposed on the extension portion and is connected with the driving trace.

According to the second aspect of the present application, a display device is provided, which comprises the aforementioned splicing display module.

### BRIEF DESCRIPTION OF THE DRAWINGS

To more clearly illustrate the technical solutions in the embodiments of the present application, a brief introduction to the drawings required for the description of the embodiments is provided below. Apparently, the drawings described below are merely some embodiments of the present application. For those skilled in the art, other drawings can be derived from these drawings without creative effort.

To understand the present application and the beneficial effects thereof more completely, the following description will be made in conjunction with the accompanying drawings, wherein the same reference numerals refer to the same parts in the following description.

FIG. 1 is a schematic structural diagram of a splicing display module provided by the embodiment of the present application;

FIG. 2 is a top view of the first substrate in the splicing display module provided by the embodiment of the present application;

FIG. 3 is a top view of the second display module in the splicing display module provided by the embodiment of the present application;

FIG. 4 is a bottom view of the second display module in the splicing display module provided by the embodiment of the present application;

FIG. 5 is a cross-sectional view of the second display module along the A-A’ direction in the splicing display module provided by the embodiment of the present application;

FIG. 6 is a schematic structural diagram of the display device provided by the embodiment of the present application.

### Reference signs:

1. first display module; 11. second substrate; 12. first substrate; 121. main body; 122. extension portion; 1221. driving trace; 13. upper polarizer; 14. lower polarizer;

2. second display module; 21. conductive substrate; 211. first sub-portion; 2111. first conductive layer; 2112. first substrate layer; 212. second sub-portion; 2121. second conductive layer; 2122. second substrate layer; 22. light-emitting component; 23. transparent sealant layer; 24. terminal;

3. conductive adhesive layer;

4. first driving circuit board; 41. first chip-on-film; 42. first circuit board;

5. second driving circuit board; 51. second chip-on-film; 52. second circuit board;

100. splicing display module; 200. housing; 1000. display device.

### DETAILED DESCRIPTION

The technical solutions in the embodiments of the present application will be clearly and completely described below with reference to the accompanying drawings in the embodiments of the present application. Obviously, the described embodiments are only some of the embodiments of the present application, but not all of the embodiments. Based on the embodiments in this application, all other embodiments obtained by those skilled in the art without creative efforts fall within the protection scope of this application.

The embodiment of the present application provides a splicing display module and a display device to solve the problem that the splicing display module has seams.

To achieve the above objective, according to the first aspect of the present application, a splicing display module is provided, which comprises a first display module and a second display module spliced to each other, wherein the first display module comprises a first substrate and a second substrate disposed opposite to each other, the first substrate comprises a main body and an extension portion, the main body and the second substrate are disposed opposite to each other, the extension portion is disposed to extend beyond the edge of the second substrate, a driving trace is disposed on the extension portion; the second display module is at least disposed on the extension portion and is connected with the driving trace.

Optionally, the second display module is partially disposed on the second substrate.

Optionally, the second display module comprises a conductive substrate and a plurality of light-emitting components, the light-emitting component is disposed on the surface of the conductive substrate away from the first substrate, the conductive substrate comprises: a first sub-portion, disposed on the second substrate; a second sub-portion, disposed the extension portion; wherein, the surface of the first sub-portion away from the first substrate is flush with the surface of the second sub-portion away from the first substrate, the surface of the second sub-portion close to the first substrate protrudes from the surface of the first sub-portion close to the first substrate.

Optionally, the thickness of the first sub-portion is less than the thickness of the second sub-portion.

Optionally, the first sub-portion is provided with at least one first conductive layer, the second sub-portion is provided with at least two second conductive layers, the number of the first conductive layers is less than the number of the second conductive layers, each of the first conductive layers is disposed on the same layer with a corresponding one of the second conductive layers.

Optionally, the surface of the second sub-portion close to the extension portion is exposed with a terminal, the terminal is connected with the driving trace.

Optionally, the splicing display module further comprises a conductive adhesive layer, the conductive adhesive layer is disposed between the extension portion and the second sub-portion.

Optionally, a plurality of first transistors are disposed in the main body, a plurality of second transistors are disposed in the extension portion, the first transistor is disposed on the same layer with the second transistor.

Optionally, the second display module is disposed to extend beyond the edge of the extension portion.

Optionally, the second substrate comprises a display area and a non-display area, the non-display area is disposed to surround the display area, the second display module covers the non-display area of one side of the second substrate close to the extension portion, and the second display module partially covers the display area of one side of the second substrate close to the extension portion.

Optionally, the first display module further comprises an upper polarizer, the upper polarizer is disposed on the surface of the second substrate away from the first substrate, the second display module covers an end of the upper polarizer close to the extension portion.

Optionally, an end of the upper polarizer close to the extension portion is disposed between the second substrate and the second display module.

Optionally, the splicing display module further comprises: a first driving circuit board, electrically connected with the main body, the first driving circuit board is configured to drive the main body; and a second driving circuit board, electrically connected with the extension portion, the second driving circuit board is configured to drive the second display module.

According to the second aspect of the present application, a display device is provided, which comprises the aforementioned splicing display module.

In the splicing display module of the embodiment of the present application, the second display module is at least disposed on the extension portion, the driving trace is disposed on the extension portion, and the second display module is connected with the driving trace, the extension portion is utilized to drive the second display module, the image displayed by the second display module may block the borders of the first substrate and the second substrate, so that the seam of the splicing display module can be reduced or even eliminated, achieving the effect of full-screen display of the splicing display module.

Other features and advantages of the present application will be described in detail in the subsequent specific embodiment.

The embodiment of the present application provides a splicing display module, the splicing display module comprises a first display module and a second display module spliced to each other, the first display module comprises a first substrate and a second substrate disposed opposite to each other, the first substrate comprises a main body and an extension portion, the main body and the second substrate are disposed opposite to each other, the extension portion is disposed to extend beyond the edge of the second substrate, a driving trace is disposed on the extension portion; the second display module is at least disposed on the extension portion and is connected with the driving trace.

In the embodiment of the present application, the second display module is at least disposed on the extension portion of the first substrate, and the second display module is connected with the driving trace, the extension portion is utilized to drive the second display module to display image, so that the seam of the splicing display module can be reduced or even eliminated, and the effect of full-screen display of the splicing display module is achieved.

Please refer to FIG. 1, FIG. 1 is a schematic structural diagram of a splicing display module provided by the embodiment of the present application, the splicing display module 100 comprises a first display module and a second display module spliced to each other, the first display module 1 is a liquid crystal display panel, the first display module 1 comprises a second substrate 11 and a first substrate 12, the first substrate 12 and the second substrate 11 are disposed opposite to each other. The first substrate 12 comprises a main body 121, the main body 121 and the second substrate 11 are disposed opposite to each other. In the thickness direction of the first display module, the main body 121 overlaps with the second substrate 11. The first display module 1 further comprises a liquid crystal layer (not shown in the figure), the liquid crystal layer is disposed between the second substrate 11 and the first substrate 12.

Please refer to FIG. 1, the first substrate 12 further comprises an extension portion 122, the extension portion 122 is disposed to extend beyond the edge of the second substrate 11, the extension portion 122 is disposed at a splicing end of the first display module 1.

In some embodiments, please refer to FIG. 1, the extension portion 122 is connected with an end of the main body 121, the main body 121 and the extension portion 122 belong to different parts of the first substrate 12, the main body 121 and the extension portion 122 form an integrated structure.

Please refer to FIG. 1, the extension portion 122 is disposed to extend beyond the edge of the second substrate, in the thickness direction of the first display module, the extension portion 122 is disposed to be apart from the second substrate 11, that is, the extension portion 122 does not overlap with the second substrate 11, it can also be considered that the size of the first substrate 12 is greater than the size of the second substrate 11.

Please refer to FIG. 1, the splicing display module 100 further comprises a second display module 2, the second display module 2 is configured to display image, the second display module 2 is at least disposed on the extension portion 122, a driving trace is disposed on the extension portion 122, the second display module 2 is connected with the driving trace.

It should be noted that, the second display module 2 is at least disposed on the extension portion 122, meaning that the second display module 2 is disposed above the extension portion 122, that is, one side of the extension portion 122 close to the second substrate 11, the second display module 2 is configured to be in direct contact with the surface of the extension portion 122 close to the second substrate 11 or be spaced apart by other film layers.

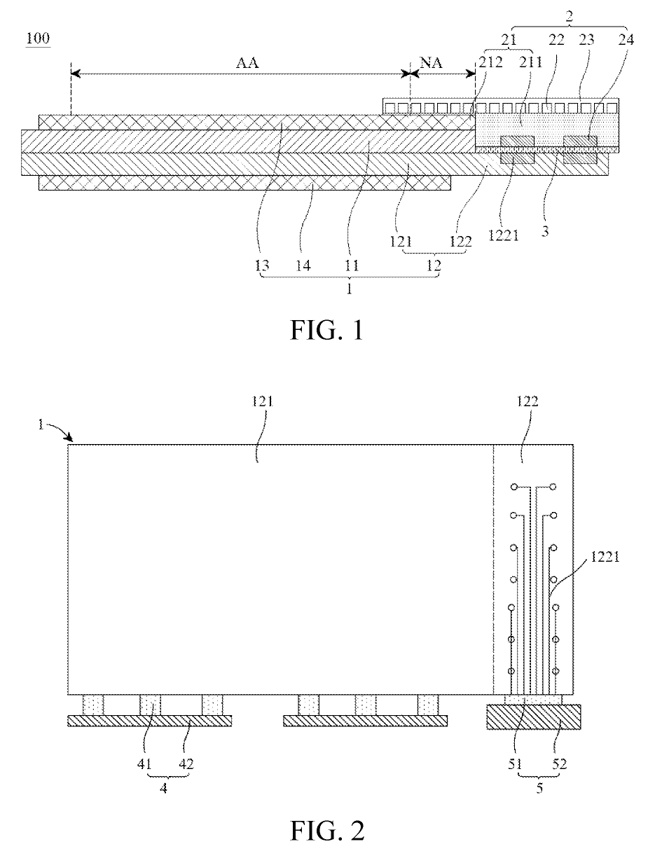

Please refer to FIG. 1 and FIG. 2, FIG. 2 is a top view of the first substrate in the splicing display module provided by the embodiment of the present application, a driving trace 1221 is disposed on the extension portion 122, the second display module 2 is electrically connected with the driving trace 1221, the second display module 2 is configured to display image under the driving of the electrical signal provided by the extension portion 122, the image displayed by the second display module 2 is configured to seamlessly connect with the image displayed by the first display module 1, so that the seam of the splicing display module can be eliminated, and the effect of full-screen display can be achieved.

In some embodiments, please refer to FIG. 1 and FIG. 2, the surface of the second display module 2 close to the first substrate 12 is exposed with a terminal 24, an auxiliary driving circuit is disposed in the extension portion 122, the auxiliary driving circuit is connected with the driving trace, the terminal 24 is electrically connected with the driving trace 1221.

In some embodiments, the first substrate 12 comprises a base substrate and a driving circuit layer (not shown in the figure) disposed on the base substrate, the main body 121 and the extension portion 122 are both provided with the driving circuit layer. Specifically, the driving circuit layer is stacked by film layers such as a metal layer, a semiconductor layer and an insulating layer, the driving circuit layer is provided with a pixel driving circuit which is configured to charge the pixel electrode to drive the liquid crystal molecule to deflect.

Specifically, please refer to FIG. 1 and FIG. 2, a pixel driving circuit (not shown in the figure) is disposed in the driving circuit layer of the main body 121, the pixel driving layer is configured to charge the pixel electrode disposed in the main body, to drive the liquid crystal molecule corresponding to the main body to deflect. An auxiliary driving circuit is disposed in the driving circuit of the extension portion 122, the extension portion 122 is not provided with the pixel electrode, the driving trace 1221 is electrically connected with the terminal 24 of the second display module 2, the driving trace 1221 is configured to drive the light-emitting component in the second display module 2 to emit light.

In some embodiments, please refer to FIG. 1, the second display module 2 is partially disposed on the second substrate 11, the image displayed by the second display module 2 is configured to seamlessly connect with the image displayed by the first display module 1, and the image displayed by the second display module 2 is configured to block the borders of the first substrate 12 and the second substrate 11, so that the seam of the splicing display module can be reduced or even eliminated, and the effect of full-screen display of the splicing display module is achieved.

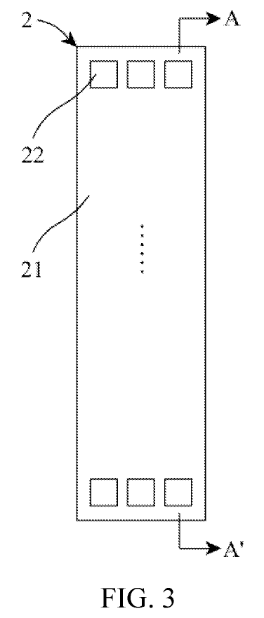

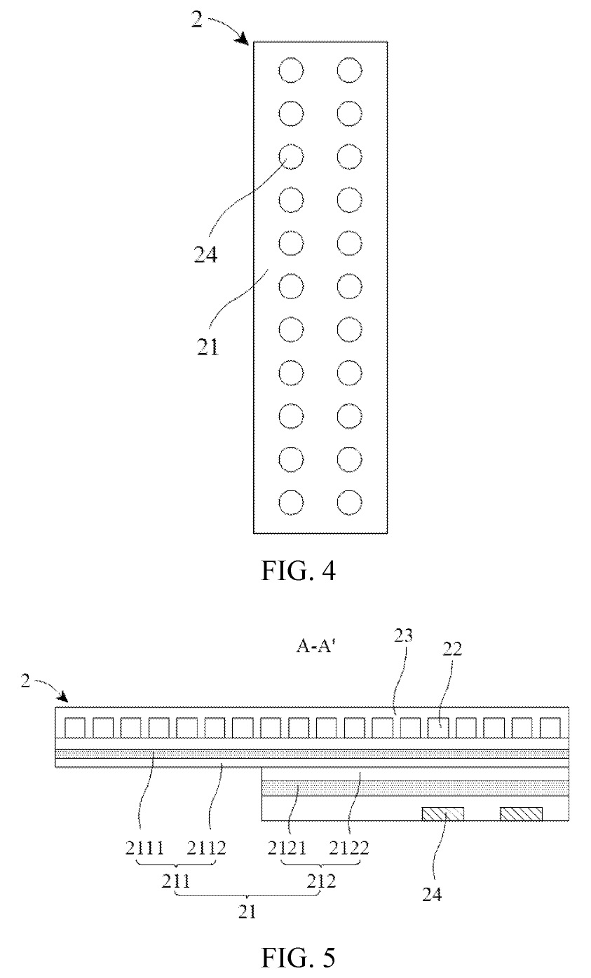

In some embodiments, please refer to FIG. 1 to FIG. 5, FIG. 3 is a top view of the second display module in the splicing display module provided by the embodiment of the present application, FIG. 4 is a bottom view of the second display module in the splicing display module provided by the embodiment of the present application, FIG. 5 is a cross-sectional view of the second display module along the A-A’ direction in the splicing display module provided by the embodiment of the present application, the second display module 2 comprises a conductive substrate 21 and a plurality of light-emitting components 22, the light-emitting component 22 is disposed on the surface of the conductive substrate 21 away from the first substrate 12, the conductive substrate 21 comprises a first sub-portion 211 and a second sub-portion 212, the first sub-portion 211 is disposed on the second substrate 11, the second sub-portion 212 is disposed on the extension portion 122 of the first substrate 12, the first sub-portion 211 and the second sub-portion 212 belong to different parts of the conductive substrate 21, the first sub-portion 211 and the second sub-portion 212 form an integrated structure.

In some embodiments, please refer to FIG. 1 to FIG. 5, the surfaces of the first sub-portion 211 and the second sub-portion 212 away from the first substrate 12 are both provided with a plurality of light-emitting components 22, the surface of the first sub-portion 211 away from the first substrate 12 is flush with the surface of the second sub-portion 212 away from the first substrate 12, the surface of the second sub-portion 212 close to the first substrate 12 protrudes from the surface of the first sub-portion 211 close to the first substrate 12, so that the light-emitting components 22 disposed on the first sub-portion 211 and the second sub-portion 212 are allowed to be at the same height, ensuring that the display effects of the first sub-portion 211 and the second sub-portion 212 are consistent.

In some embodiments, please refer to FIG. 5, the thickness of the first sub-portion 211 is less than the thickness of the second sub-portion 212, by increasing the thickness of the second sub-portion 212, the height difference between the upper surface of the second substrate 11 and the upper surface of the extension portion 122 can be compensated, so that the light-emitting components 22 disposed on the first sub-portion 211 and the second sub-portion 212 are allowed to be at the same height, ensuring that the display effects of the first sub-portion 211 and the second sub-portion 212 are consistent.

In some embodiments, the first sub-portion 211 of the conductive substrate 21 comprises at least one first conductive layer 2111 and first substrate layers 2112 disposed at the upper side and the lower side of the first conductive layer 2111, the second sub-portion 212 comprises at least two second conductive layers 2121 and second substrate layers 2122 disposed at the upper side and the lower side of the second conductive layer 2121, the number of the first conductive layers 2111 is less than the number of the second conductive layers 2121, so that the thickness of the first sub-portion 211 is less than the thickness of the second sub-portion 212.

In some embodiments, each of the first conductive layers 2111 in the first sub-portion 211 is disposed on the same layer with the corresponding one of the second conductive layers 2121 in the second sub-portion 212, each first substrate layer 2112 is disposed on the same layer with the corresponding second substrate layer 2122.

In some embodiments, the light-emitting component 22 is a light emitting diode, in particular, the light-emitting component 22 can comprise a red light emitting diode, a green light emitting diode and a blue light emitting diode, the red light emitting diode, the green light emitting diode and the blue light emitting diode are configured to be disposed in a way of pixel arrangement.

In some other embodiments, the type of light-emitting component 22 is not limited to the light-emitting diode described in the above embodiment, it can also be light-emitting components such as a mini light-emitting diode, a micro light-emitting diode or an organic light-emitting diode.

In some embodiments, the second display module 2 further comprises a transparent sealant layer 23, the transparent sealant layer 23 is disposed on the conductive substrate 21 and covers the light-emitting component 22.

In some embodiments, please refer to FIG. 1 to FIG. 5, the terminal 24 is exposed on the surface of the second sub-portion 212 close to the first substrate 12.

In some embodiments, please refer to FIG. 1, the splicing display module 100 further comprises a conductive adhesive layer 3, the conductive adhesive layer 3 is disposed between the extension portion 122 and the second sub-portion 212, the terminal 24 exposed on the surface of the second sub-portion 212 close to the extension portion 122 is electrically connected with the driving trace 1221 exposed on the surface of the extension portion 122 through the conductive adhesive layer 3.

In some embodiments, the adhesive material chosen for the conductive adhesive layer 3 is an anisotropic conductive adhesive, the anisotropic conductive adhesive is configured to provide conductive function in a specific direction, the anisotropic conductive adhesive mainly comprises a base material and conductive particles, the base material comprises polyimide, acrylic, and epoxy resin.

In some embodiments, a plurality of first transistors are disposed in the main body 121, a plurality of second transistors are disposed in the extension portion 122, the first transistor and the second transistor are disposed in the same layer, the structure of the first transistor is identical to the structure of the second transistor, the first transistor and the second transistor can be manufactured in a same manufacturing process.

In some embodiments, please refer to FIG. 1, one end of the second display module 2 close to the extension portion 122 extends beyond one end disposed at the edge of the extension portion 122. By extending the second display module 2, one end of the second display module 2 close to the extension portion 122 is disposed to extend beyond the edge of the extension portion 122, so that the second display modules 2 of the two adjacent splicing display modules 100 are configured to splice directly, the seam between the two adjacent splicing display modules 100 can be reduced or even eliminated.

In some embodiments, the length of the end of the second display module 2 close to the extension portion 122 extending beyond the extension portion 122 is 1 mm. In practical application, the length of the end of the second display module 2 close to the extension portion 122 extending beyond the extension portion 122 is not only limited to 1 mm in the aforementioned embodiment, but also can be 0.8 mm, 0.9 mm, 1.1 mm or 1.2 mm, etc.

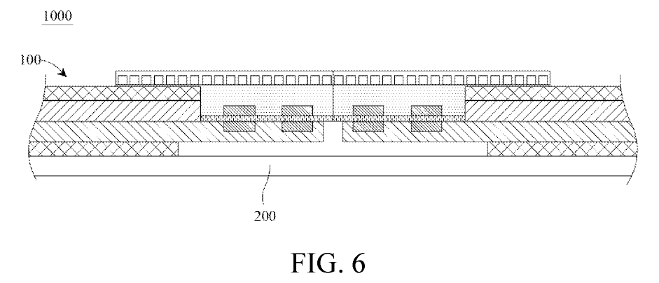

In some embodiments, please refer to FIG. 6, the end of the extension portion 122 close to the second display module 2 is spaced apart from the first substrate 12 of the other adjacent splicing display module 100. Since the material of the base substrate of the first substrate 12 is glass, in case where the first substrates 12 of the two adjacent splicing display modules 100 are spliced directly, the base substrate of the first substrate 12 is easily to be bumped, resulting in damage to the first substrate 12. The ends of the two adjacent first substrates 12 close to each other are spaced apart, the risk that the first substrate 12 is damaged due to bump in the process of splicing assembly or transporting can be reduced. Furthermore, since the splicing display module 100 further comprises a backlight module (not shown in the figure), by configuring the ends of the two adjacent first substrates 12 which are close to each other to be spaced apart, a certain buffer space can be reserved for the structural design of the backlight module, the difficulty of design and assembly of the splicing display module can be reduced.

In some embodiments, please refer to FIG. 1, the second substrate 11 comprises a display area AA and non-display area NA, the non-display area NA is disposed to surround the display area AA, the second display module 2 covers the non-display area NA of one side of the second substrate 11 close to the extension portion 122, and the second display module 2 partially covers the display area AA of one side of the second substrate 11 close to the extension portion 122.

In the present embodiment, the second display module 2 not only covers the non-display area NA of one side of the second substrate 11 close to the extension portion 122, but also partially covers the display area AA of one side of the second substrate 11 close to the extension portion 122, ensuring that the image displayed by the display area AA of the second substrate 11 is more coherent with the image displayed by the second display module 2, so that the seam of the splicing display module can be further reduced or even eliminated, and the effect of full-screen display of seamlessly splicing can be achieved.

In some embodiments, please refer to FIG. 1, the first display module 1 further comprises an upper polarizer 13, the upper polarizer 13 is disposed on the surface of the second substrate 11 away from the first substrate 12, the second display module 2 covers an end of the upper polarizer 13 close to the extension portion 122.

In some embodiments, please refer to FIG. 1, an end of the upper polarizer 13 close to the extension portion 122 is disposed between the second substrate 11 and the second display module 2.

In some embodiments, please refer to FIG. 1, the first display module 1 further comprises a lower polarizer 14, the lower polarizer 14 is disposed on the surface of the first substrate 12 away from the second substrate 11.

In some embodiments, please refer to FIG. 2, the splicing display module 100 further comprises a first driving circuit board 4 and a second driving circuit board 5, the first driving circuit board 4 is electrically connected with the main body 121, the first driving circuit board 4 is configured to drive the main body 121. The second driving circuit board 5 is electrically connected with the extension portion 122, the second driving circuit board 5 is configured to drive the second display module 2.

The first driving circuit board 4 comprises a plurality of first chip-on-films 41 and a first circuit board 42, the first circuit board 42 is electrically connected with the main body 121 through the first chip-on-film 41. The first chip-on-film 41 is composed of a flexible circuit board and a first driving chip which is connected with the flexible circuit board in a bonding manner. The second driving circuit board 5 comprises a second chip-on-film 51 and a second circuit board 52, the second circuit board 52 is electrically connected with the extension board 122 through the second chip-on-film 51. The second chip-on-film 51 is composed of a flexible circuit board and a second driving chip which is connected with the flexible circuit board in a bonding manner.

In some embodiments, please refer to FIG. 2, the splicing display module 100 comprises two first driving circuit boards 4 and a second driving circuit board 5. In practical application, the number of the first driving circuit board 4 and the number of the second driving circuit board 5 in the splicing display module 100 can be disposed according to the actual needs, which is not limited here.

According to the splicing display module provided by the aforementioned embodiment of the present application, the embodiment of the present application further provides a display device, please refer to FIG. 6, FIG. 6 is a schematic structural diagram of the display device provided by the embodiment of the present application, the display device 1000 comprises at least two splicing display modules 100 and a housing 200, the at least two splicing display modules 100 are disposed on the housing 200 in a splicing manner. The splicing display module 100 can be the splicing display module provided by any one of the aforementioned embodiments. The display device provided by the embodiment of the present application can achieve the same technical effect as the splicing display module provided by any one of the aforementioned embodiments, which will not be described here.

The beneficial effects of the embodiments of the present application are as follows. The embodiments of the present application provides a splicing display module and a display device, the splicing display module comprises a first display module and a second display module spliced to each other, the first display module comprises a first substrate and a second substrate disposed opposite to each other, the main body of the first substrate and the second substrate are disposed opposite to each other, the extension portion of the first substrate is disposed to extend beyond the edge of the second substrate, the second display module is at least disposed on the extension portion and is connected with the driving trace of the extension portion, the extension portion is utilized to drive the second display module, the image displayed by the second display module is configured to block the borders of the first substrate and the second substrate, so that the seam of the splicing display module can be reduced or even eliminated, and the effect of full-screen display of the splicing display module is achieved.

In the description of this application, the terms “first” and “second” are used for descriptive purposes only, and cannot be understood as indicating or implying relative importance or implicitly indicating the number of indicated technical features. Therefore, the features defined as “first” and “second” may explicitly or implicitly include one or more features. In the description of this application, “plurality” means two or more than two, unless otherwise explicitly and specifically limited.

In the above embodiments, each embodiment is described with its own emphasis. For parts that are not described in detail in a certain embodiment, please refer to the relevant descriptions of other embodiments.

The embodiments, implementation modes and related technical features of the present application can be combined and replaced with each other without conflict.

The above are only preferred embodiments of the present application and are not intended to limit the present application in any form. However, any simple modifications or equivalents to the above embodiments may be made based on the technical essence of the present application without departing from the content of the technical solution of the present application. Changes and modifications still fall within the scope of the technical solution of this application.

1. A splicing display module, comprising a first display module and a second display module spliced to each other, wherein
the first display module comprises a first substrate and a second substrate disposed opposite to each other, the first substrate comprises a main body and an extension portion, the main body and the second substrate are disposed opposite to each other, the extension portion is disposed to extend beyond the edge of the second substrate, a driving trace is disposed on the extension portion;
the second display module is at least disposed on the extension portion and is connected with the driving trace.

2. The splicing display module according to claim 1, wherein the second display module is partially disposed on the second substrate.

3. The splicing display module according to claim 2, wherein the second display module comprises a conductive substrate and a plurality of light-emitting components, the light-emitting component is disposed on the surface of the conductive substrate away from the first substrate, the conductive substrate comprises:
a first sub-portion, disposed on the second substrate;
a second sub-portion, disposed the extension portion;
wherein, the surface of the first sub-portion away from the first substrate is flush with the surface of the second sub-portion away from the first substrate, the surface of the second sub-portion close to the first substrate protrudes from the surface of the first sub-portion close to the first substrate.

4. The splicing display module according to claim 3, wherein the thickness of the first sub-portion is less than the thickness of the second sub-portion.

5. The splicing display module according to claim 3, wherein the first sub-portion is provided with at least one first conductive layer, the second sub-portion is provided with at least two second conductive layers, the number of the first conductive layers is less than the number of the second conductive layers, each of the first conductive layers is disposed on the same layer with a corresponding one of the second conductive layers.

6. The splicing display module according to claim 3, wherein the surface of the second sub-portion close to the extension portion is exposed with a terminal, the terminal is connected with the driving trace.

7. The splicing display module according to claim 3, wherein the splicing display module further comprises a conductive adhesive layer, the conductive adhesive layer is disposed between the extension portion and the second sub-portion.

8. The splicing display module according to claim 1, wherein a plurality of first transistors are disposed in the main body, a plurality of second transistors are disposed in the extension portion, the first transistor is disposed on the same layer with the second transistor.

9. The splicing display module according to claim 1, wherein the second display module is disposed to extend beyond the edge of the extension portion.

10. The splicing display module according to claim 1, wherein the second substrate comprises a display area and a non-display area, the non-display area is disposed to surround the display area, the second display module covers the non-display area of one side of the second substrate close to the extension portion, and the second display module partially covers the display area of one side of the second substrate close to the extension portion.

11. The splicing display module according to claim 10, wherein the first display module further comprises an upper polarizer, the upper polarizer is disposed on the surface of the second substrate away from the first substrate, the second display module covers an end of the upper polarizer close to the extension portion.

12. The splicing display module according to claim 11, wherein an end of the upper polarizer close to the extension portion is disposed between the second substrate and the second display module.

13. The splicing display module according to claim 1, wherein the splicing display module further comprises:
a first driving circuit board, electrically connected with the main body, the first driving circuit board is configured to drive the main body; and
a second driving circuit board, electrically connected with the extension portion, the second driving circuit board is configured to drive the second display module.

14. The splicing display module according to claim 1, wherein in the thickness direction of the first display module, the main body overlaps with the second substrate, and the extension portion does not overlap with the second substrate.

15. The splicing display module according to claim 1, wherein a first end of the first substrate is spaced apart from a second end of the first substrate adjacent thereto, and wherein the first end is close to the second end.

16. The splicing display module according to claim 1, wherein the first display module further comprises a lower polarizer, the lower polarizer is disposed on the surface of the first substrate away from the second substrate.

17. A display device, wherein the display device comprises the splicing display module according to claim 1.

18. The display device according claim 17, wherein the splicing display module comprises a first display module and a second display module spliced to each other, the second display module is partially disposed on the second substrate.

19. The display device according claim 18, wherein the first display module comprises a first substrate and a second substrate disposed opposite to each other, the first substrate comprises a main body and an extension portion, the main body and the second substrate are disposed opposite to each other, the extension portion is disposed to extend beyond the edge of the second substrate, a driving trace is disposed on the extension portion;
the second display module is at least disposed on the extension portion and is connected with the driving trace;
a plurality of first transistors are disposed in the main body, a plurality of second transistors are disposed in the extension portion, the first transistor is disposed on the same layer with the second transistor.

20. The display device according claim 18, wherein the first display module comprises a first substrate and a second substrate disposed opposite to each other, the first substrate comprises a main body and an extension portion, the main body and the second substrate are disposed opposite to each other, the extension portion is disposed to extend beyond the edge of the second substrate, a driving trace is disposed on the extension portion;
the second display module is at least disposed on the extension portion and is connected with the driving trace;
the second display module is disposed to extend beyond the edge of the extension portion.
